(19) United States
(12) Patent Application Publication
(10) Pub. No.: US 2025/0374545 A1
(43) Pub. Date: Dec. 4, 2025

(54) SELF-SELECTING MEMORY DEVICE AND MEMORY APPARATUS INCLUDING THE SAME

(71) Applicant: Samsung Electronics Co., Ltd., Suwon-si (KR)

(72) Inventors: Kiyeon YANG, Suwon-si (KR); Youngjae KANG, Suwon-si (KR); Jongbong PARK, Suwon-si (KR); Minwoo CHOI, Suwon-si (KR)

(73) Assignee: Samsung Electronics Co., Ltd., Suwon-si (KR)

(21) Appl. No.: 18/941,535

(22) Filed: Nov. 8, 2024

(30) Foreign Application Priority Data
May 31, 2024 (KR) 10-2024-0071812

(51) Int. Cl. H10B 43/35; G11C 11/4097; H10B 43/20; H10B 43/40

(52) U.S. Cl. CPC H10B 43/35; G11C 11/4097; H10B 43/20; H10B 43/40

(57) ABSTRACT

Provided are a memory device and a memory apparatus including the same. The memory device includes a first electrode, a second electrode spaced apart from the first electrode, a memory layer between the first and second electrodes, having ovonic threshold switching characteristic, having a threshold voltage that changes according to a polarity of and/or a strength of an applied voltage, and including an amorphous chalcogenide-based material, and at least one intermediate layer including a crystalline chalcogenide-based material between at least one of the first and second electrodes and the memory layer. The memory device may include a first intermediate layer disposed between the first electrode and the memory layer and including a crystalline chalcogenide-based material and/or a second intermediate layer between the second electrode and the memory layer and including a crystalline chalcogenide-based material.

### CROSS-REFERENCE TO RELATED APPLICATION

This application is based on and claims priority under 35 U.S.C. § 119 to Korean Patent Application No. 10-2024-0071812, filed on May 31, 2024, in the Korean Intellectual Property Office, the disclosure of which is incorporated by reference herein in its entirety.

### BACKGROUND

Various example embodiments relate, in general, to a self-selecting memory device and/or a memory apparatus including the same.

As electronic products become lighter, thinner, and simpler, the demand for high integration of memory apparatuses is increasing. A memory apparatus having a cross-point structure has a structure in which rows/word lines and columns/bit lines intersect vertically and memory cells are arranged at intersection regions. This structure has small memory cells on a plane, but addressing the memory cells requires or uses a memory cell with a structure in which a 2-terminal selector for preventing or reducing a sneak current between neighboring memory cells is connected in series to a memory device. As a result, the aspect ratio of a unit memory cell increases, the manufacturing process of the memory cell becomes complicated, and there is a limit in increasing the memory capacity of a memory apparatus by reducing a pitch between electrodes of the memory device.

### SUMMARY

Various example embodiments provide a self-selecting memory device simultaneously performing a selector function and a memory function, and/or a memory apparatus including the same.

Alternatively or additionally, provided are a self-selecting memory device with enhanced durability by preventing or reducing diffusion of memory layer constituent elements in an electrode direction, and/or a memory apparatus including the same.

Additional aspects will be set forth in part in the description which follows and, in part, will be apparent from the description, or may be learned by practice of the presented embodiments of the disclosure.

According to various example embodiments, a memory device includes a first electrode, a second electrode spaced apart from the first electrode, a memory layer between the first and second electrodes, having an ovonic threshold switching characteristic, having a changeable threshold voltage that changes according to a polarity of and a strength of an applied voltage, and including an amorphous chalcogenide-based material, and at least one of a first intermediate layer between the first electrode and the memory layer and including a first crystalline chalcogenide-based material and a second intermediate layer between the second electrode and the memory layer and including a second crystalline chalcogenide-based material, the first crystalline chalcogenide-based material the same or different from the second chalcogenide material.

Alternatively or additionally according to various example embodiments, a memory apparatus including a plurality of memory cells, wherein each of the plurality of memory cells may include a first electrode, a second electrode spaced apart from the first electrode, a memory layer between the first and second electrodes, having ovonic threshold switching characteristic, having a changeable threshold voltage that changes according to a polarity of and/or a strength of an applied voltage, and including an amorphous chalcogenide-based material, and at least one of a first intermediate layer between the first electrode and the memory layer and including a first crystalline chalcogenide-based material and a second intermediate layer between the second electrode and the memory layer and including a second crystalline chalcogenide-based material, the first crystalline chalcogenide-based material the same or different from the second chalcogenide material.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 3 are schematic cross-sectional views showing a structure of memory devices according to various example embodiments;

FIG. 4 is a graph showing voltage-current characteristics of a memory layer of a memory device according to various example embodiments;

FIG. 5A is a graph illustrating bias voltages for a SET operation and a read operation in a memory device according to various example embodiments;

FIG. 5B is a graph illustrating bias voltages for a RESET operation and a read operation in a memory device according to various example embodiments;

FIG. 6A is a conceptual diagram showing a trap state inside a memory layer in a pristine state of a memory layer of a memory device according to various example embodiments, and FIG. 6B is a diagram schematically showing an energy band diagram for the memory layer in the pristine state;

FIG. 7A is a conceptual diagram illustrating a trap state inside a memory layer after applying a positive (+) bias voltage for first-firing to the memory layer in the pristine state;

FIG. 7B schematically shows an energy band diagram for a memory layer region near a first electrode after first-firing;

FIG. 7C schematically shows an energy band diagram for a memory layer region near the second electrode after first-firing;

FIG. 8A is a conceptual diagram illustrating a trap state inside a memory layer after applying a negative (−) bias voltage to a first-fired memory layer;

FIG. 8B schematically shows an energy band diagram for a memory layer region near a first electrode after applying a negative (−) bias voltage;

FIG. 8C schematically shows an energy band diagram for a memory layer region near the second electrode after applying a negative (−) bias voltage;

FIG. 9A is a graph illustrating a bias voltage for a RESET operation and a SET operation for writing applied to a memory layer of a memory device according to various example embodiments;

FIG. 9B is a graph showing voltage-current characteristics according to a magnitude (strength) of a write voltage applied to a memory layer of a memory device according to various example embodiments;

FIG. 10 schematically shows a band diagram of a space charge region formed by a RESET operation in a memory device according to various example embodiments;

FIG. 11 is a simulation result illustrating an I-V curve showing the generation of a memory window in a memory device according to an example embodiment by modeling the result shown in FIG. 10;

FIG. 12 is a graph showing an elemental composition ratio of materials of a memory layer of a memory device according to various example embodiments;

FIG. 13 illustrates a transmission electron microscope (TEM) image of a memory device sample according to a comparative example that is actually manufactured;

FIGS. 14A, 14B, and 14C illustrate results of element mapping for a GeAsSe-based memory layer of the memory device sample of the comparative example shown in FIG. 13;

FIG. 15 is a schematic cross-sectional view showing a structure of a memory device according to a comparative example;

FIG. 16 shows a comparison of diffusion of memory layer constituent elements in a memory device according to a comparative example;

FIG. 17 shows a comparison of diffusion of memory layer constituent elements in a memory device according to various example embodiments.

FIG. 18 is a schematic perspective view showing a structure of a memory apparatus according to various example embodiments;

FIG. 19 is an enlarged view of a portion of one memory cell in the memory apparatus shown in FIG. 18;

FIG. 20 is a plan view illustrating an operation of selecting a specific memory cell in the memory apparatus shown in FIG. 18;

FIG. 21 is a schematic perspective view showing a structure of a memory apparatus according to another embodiment;

FIG. 22 is a schematic vertical cross-sectional view of a configuration of one memory cell in the memory apparatus shown in FIG. 21;

FIG. 23 is a schematic horizontal cross-sectional view of a structure of one memory cell in the memory apparatus shown in FIG. 21;

FIG. 24 is a schematic conceptual diagram of a device architecture applicable to electronic apparatuses according to example embodiments;

FIG. 25 is a block diagram of a memory system according to an example embodiment; and

FIG. 26 is a block diagram showing a neuromorphic apparatus according to an example embodiment and an external device connected thereto.

### DETALLED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereafter, embodiments will be described more fully with reference to the accompanying drawings. In the drawings, like reference numerals refer to like elements, and in the drawings, sizes of constituent elements may be exaggerated for clarity and convenience of explanation. The following embodiments described below are merely illustrative, and various modifications may be possible from the embodiments of the disclosure.

Hereinafter, when a position of an element is described using an expression “above” or “on”, the position of the element may include not only the element being “immediately on/under/left/right in a contact manner” but also being “on/under/left/right in a non-contact manner”. Singular forms include the plural forms unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise.

Also, as used herein, the term “units” or “modules” denote units or modules that process at least one function or operation, and may be realized by hardware, software, or a combination of hardware and software.

In addition, the connecting lines or connecting members between the components shown in the drawings are merely illustrative of functional connections and/or physical or circuit connections. In a practical device, the connections between the components may be represented by various functional connections, physical connections, or circuit connections that may be replaced or added.

All examples or example terms (for example, etc.) are simply used to explain in detail the technical scope of the disclosure, and thus, the scope of the disclosure is not limited by the examples or the example terms as long as it is not defined by the claims.

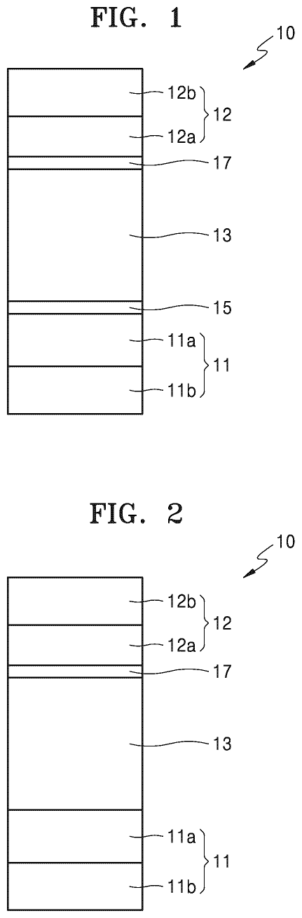

FIG. 1 is a schematic cross-sectional view of a structure of a memory device 10 according to various example embodiments.

Referring to FIG. 1, the memory device 10 according to various example embodiments includes a first electrode 11, a second electrode 12 spaced apart from the first electrode 11 and facing the first electrode 11, a memory layer 13 including an amorphous chalcogenide-based material disposed between the first electrode 11 and the second electrode 12, and at least one intermediate layer disposed between at least one of the first and second electrodes 11 and 12 and the memory layer 13 and including a crystalline chalcogenide-based material. FIG. 1 shows an example including both a first intermediate layer 15 that is disposed between the first electrode 11 and the memory layer 13 and includes a crystalline chalcogenide-based material and a second intermediate layer 17 that is disposed between the second electrode 12 and the memory layer 13 and includes a crystalline chalcogenide-based material In this way, the memory device 10 according to various example embodiments may include at least one intermediate layer of the first intermediate layer 15 disposed between the first electrode 11 and the memory layer 13 and the second intermediate layers 17 disposed between the second electrode 12 and the memory layer 13, and the at least one intermediate layer may be provided to include a crystalline chalcogenide-based material.

The first electrode 11 and the second electrode 12 may function to apply a voltage, such as to create a voltage difference, to the memory layer 13. To this end, the first electrode 11 and the second electrode 12 may each include an electrode layer. In some examples, at least one of the first electrode 11 and the second electrode 12 may include a plurality of layers including an electrode layer. For example, at least one of the first electrode 11 and the second electrode 12 may include an electrode layer and a barrier layer.

As an example illustrated in FIG. 1, the first electrode 11 may include an electrode layer 11b and a barrier layer 11a, and the second electrode 11 may include an electrode layer 12b and a barrier layer 12a. FIG. 1 and the following example embodiments show an example in which the first electrode 11 and the second electrode 12 each include an electrode layer and a barrier layer, but example embodiments are not limited thereto. For example, the first electrode 11 and the second electrode 12 may each include only an electrode layer. As another example, one of the first electrode 11 and the second electrode 12 may include an electrode layer and a barrier layer, and the other may include only an electrode layer.

The barrier layer 11a and/or the barrier layer 12a may prevent or reduce the likelihood of and/or impact from mixing between the metal material of the electrode layers 11 and 12 and the amorphous chalcogenide-based material of the memory layer 13. The barrier layer may include an amorphous layer. Additionally or alternatively, the barrier layer may include a carbon-based material. For example, the barrier layer may include at least one of carbon, carbon nitride, or carbon silicon. For example, the barrier layer may include an amorphous carbon layer. Additionally or alternatively, the barrier layer may include an amorphous layer including carbon nitride or carbon silicon.

The barrier layer 11a of the first electrode 11 may include the same material as the barrier layer 12a of the second electrode 12 but is not limited thereto. For example, the barrier layer 11a of the first electrode 11 and the barrier layer 12a of the second electrode 12 may each include an amorphous carbon layer. In some example embodiments, the barrier layer 11a of the first electrode 11 may include an amorphous carbon layer and may or may not include carbon nitride and/or carbon silicon, and the barrier layer 12a of the second electrode 12 may include an amorphous layer including carbon nitride and/or carbon silicon and may not include an amorphous carbon layer. As another example, the barrier layer 11a of the first electrode 11 may include an amorphous layer including carbon nitride and/or carbon silicon, and the barrier layer 12a of the second electrode 12 may be or may include an amorphous carbon layer.

Each of the electrode layers 11b and 12b of the first electrode 11 and the second electrode 12 may independently include metal, conductive metal nitride, conductive metal oxide, or any combination thereof. For example, the electrode layers 11b and 12b of the first electrode 11 and the second electrode 12 may each independently include at least one of titanium nitride (TiN), titanium silicon nitride (TiSiN), titanium carbon nitride (TiCN), titanium carbon silicon nitride (TiCSIN), titanium aluminum nitride (TiAlN), tantalum (Ta), tantalum nitride (TaN), tantalum silicon nitride (TaSiN), tantalum aluminum nitride (TaAlN), tungsten silicide (WSi), titanium tungsten (TiW)), molybdenum nitride (MoN), niobium nitride (NbN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), titanium aluminum (TiAl), titanium oxynitride (TION), titanium aluminum oxynitride (TiAlON), tungsten oxynitride (WON), tantalum oxynitride (TaON), silicon carbon (SiC), silicon carbon nitride (SiCN), carbon nitride (CN), tantalum carbon nitride (TaCN), tungsten (W), tungsten nitride (WN), carbon (C), or any combination thereof. The electrode layer 11b of the first electrode 11 may include the same material as the electrode layer 12b of the second electrode 12 but is not limited thereto. The electrode layer 11b of the first electrode 11 and the electrode layer 12b of the second electrode 12 may include different materials or may include at least one component different from each other.

The memory layer 13 may include an amorphous chalcogenide-based material. The memory layer 13 may have an ovonic threshold switching (OTS) characteristic that has a high-resistance state when a voltage lower than a threshold voltage (e.g., a voltage with a lower absolute value) is applied and a low resistance state when a voltage higher than the threshold voltage (e.g., a voltage with a higher absolute value) is applied. The memory device 10 according to various example embodiments may perform a selector function by using the ovonic threshold switching characteristic of the memory layer 13. Also, the memory layer 13 may have memory characteristics in which a threshold voltage shifts depending on the polarity of, and/or a strength of, an applied bias voltage. Accordingly, the memory device 10 may have characteristics of a self-selecting memory that may perform both a memory function and a selector function with only a single memory layer 13. In some example embodiments, there may not be a separate switching device, such as a separate transistor, for accessing the memory.

In this way, the memory layer 13 may include an amorphous chalcogenide-based material, for example, an amorphous multi-element chalcogenide-based material with ovonic threshold switching characteristic and a threshold voltage that changes with a polarity and an intensity of an applied voltage.

For example, the memory layer 13 may include a GeAsSe and/or a GeSbSe based amorphous chalcogenide material. In some examples, the memory layer 13 may include an amorphous chalcogenide-based material including at least one chalcogen element selected from Se, Te, and S and at least one selected from Ge, As, and Sb. In some examples, the memory layer 13 may further include at least one of In, Al, C, B, Sr, Ga, O, N, Si, Ca, P, and S to improve resistance and/or threshold voltage drift characteristics. At this time, the content of at least one element of In, Al, C, B, Sr, Ga, O, N, Si, Ca, P and S in the memory layer 13 may be, for example, in a range from about 0 to about 10 at %, for example, in a range from about 1 at % to about 8 at %, or about 3 at % to about 5 at %.

For example, the memory layer 13 may include an amorphous chalcogenide material layer including at least one of GeAsSe, GeSbSe, GeAsSeln, GeAsSeSIn, GeAsSeSb, GeAsSeSbIn, GeAsSeTe, GeAsSeTeln, GeAsSeAl, GeAsSeAlln, GeAsSeGa, GeSbSeln, GeSbSeN, GeSbSeNIn, GeSe, GeSeln, GeS, GeSIn, GeCTe, GeCTeN, and GeSbSeN.

The first intermediate layer 15 may be provided to prevent or reduce the likelihood of and/or impact from a constituent element of the memory layer 13 from diffusing into the first electrode 11, and may include a crystalline chalcogenide-based material. The second intermediate layer 17 may be provided to prevent or reduce the likelihood of and/or impact from a constituent element of the memory layer 13 from diffusing into the second electrode 12 and may include a crystalline chalcogenide-based material. The first intermediate layer 15 and the second intermediate layer 17 may each be formed to a particular thickness, e.g. a predetermined thickness, for example, about 5 nm or less. The thicknesses of the first intermediate layer 15 and the second intermediate layer 17 may be the same or different from each other. The thickness of each of the first intermediate layer 15 and the second intermediate layer 17 may be determined within a range that does not cause significant performance degradation compared to a structure that includes only one of the first intermediate layer 15 and the second intermediate layer 17 or neither of the two. For example, the thickness of each of the first intermediate layer 15 and the second intermediate layer 17 may be determined within a range that does not increase electrode resistances of the first electrode 11 and the second electrode 12 to a significant extent.

In this way, each of the first intermediate layer 15 and the second intermediate layer 17 may have a small thickness and may include a crystalline chalcogenide-based material, and thus, may have low resistance. Therefore, each of the first intermediate layer 15 and the second intermediate layer 17 may prevent or reduce the likelihood of and/or impact from diffusion of a constituent element forming the memory layer 13 due to a strong electric field applied to the memory layer 13 including an amorphous chalcogenide-based material for a self-selecting memory operation while functioning like a metal electrode material. For example, each of the first intermediate layer 15 and the second intermediate layer 17 may prevent or reduce the constituent element of the memory layer 13 from diffusing into the first electrode 11 and the second electrode 12. In addition, as the self-selection memory operation of the memory device 10 according to various example embodiments is repeated, each of the first intermediate layer 15 and the second intermediate layer 17 may prevent or reduce electrode materials including other metals from diffusing into the memory layer 13 including an amorphous chalcogenide-based material and causing changes in an electrical characteristic of the self-selecting memory. Here, when at least one of the first electrode 11 and the second electrode 12 includes only an electrode layer without a barrier layer, the first intermediate layer 15 or the second intermediate layer 17 may prevent or reduce an element constituting the memory layer 13 from diffusing into an electrode layer 11b or 12b. In addition, when at least one of the first electrode 11 and the second electrode 12 includes a barrier layer and an electrode layer, the first intermediate layer 15 or the second intermediate layer 17 may prevent or reduce an element constituting the memory layer 13 from diffusing into a barrier layer 11a or 12a.

The first intermediate layer 15 and the second intermediate layer 17 may independently or concurrently include, for example, a crystalline chalcogenide-based material including at least one of germanium (Ge), arsenic (As), and selenium (Se). In addition, each of the first intermediate layer 15 and the second intermediate layer 17 may independently include a crystalline chalcogenide-based material including at least one chalcogen element selected from Se, Te, and S, as well as at least one element selected from Ge, As, and Sb. For example, the first intermediate layer 15 may include a crystalline chalcogenide-based material layer including Ge, or As and Se, or Ge and Se, or Ge and Te, or Sb and Te. The second intermediate layer 17 may include a crystalline chalcogenide-based material layer including Ge, As and Se, or Ge and Se, or Ge and Te, or Sb and Te. The first intermediate layer 15 and the second intermediate layer 17 may include the same crystalline chalcogenide-based material but are not limited thereto. The first intermediate layer 15 and the second intermediate layer 17 may include different crystalline chalcogenide-based materials from each other. For example, the first intermediate layer 15 and the second intermediate layer 17 may include crystalline chalcogenide-based materials that have different chalcogen elements each other or may include crystalline chalcogenide-based materials in which at least one element is different. Here, at least one of the first intermediate layer 15 and the second intermediate layer 17 may include the same chalcogen element as that of the memory layer 13 or may include the same or similar chalcogenide-based material as the memory layer 13, but may differ in that it is made of crystalline material. As another example, at least one of the first intermediate layer 15 and the second intermediate layer 17 may include a chalcogen element different from that of the memory layer 13.

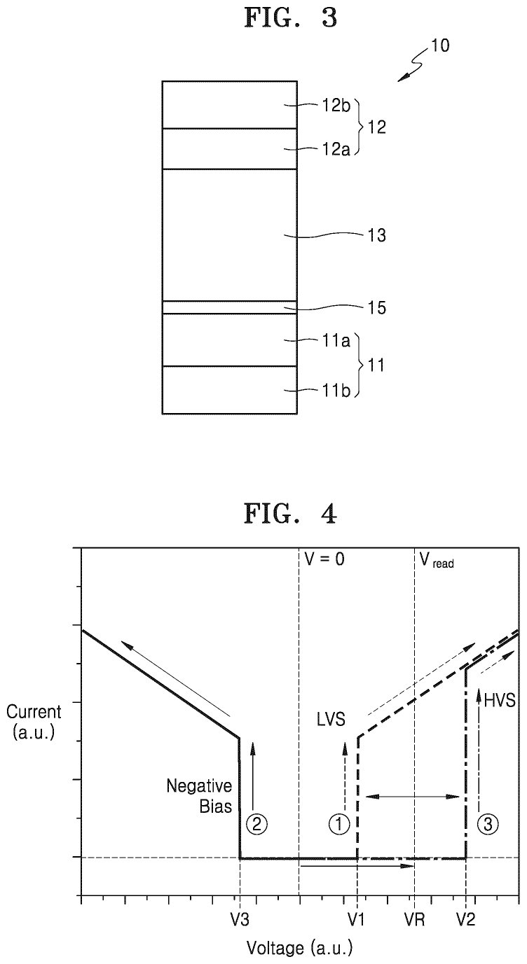

In FIG. 1, as an example, it shows that the first intermediate layer 15 is provided between the first electrode 11 and the memory layer 13 and the second intermediate layer 17 is provided between the second electrode 12 and the memory layer 13, but is not limited thereto. For example, as illustrated in FIG. 2, it may be formed into a structure in which the memory device 10 according to various example embodiments includes the second intermediate layer 17 between the second electrode 12 and the memory layer 13 without the first intermediate layer 15. Also, as illustrated in FIG. 3, it may be formed into a structure that the memory device 10 according to various example embodiments includes the first intermediate layer 15 between the first electrode 11 and the memory layer 13 without the second intermediate layer 17.

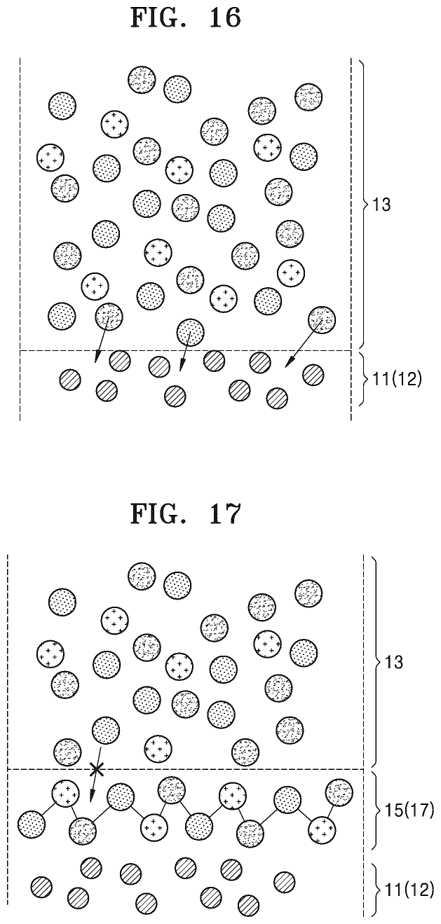

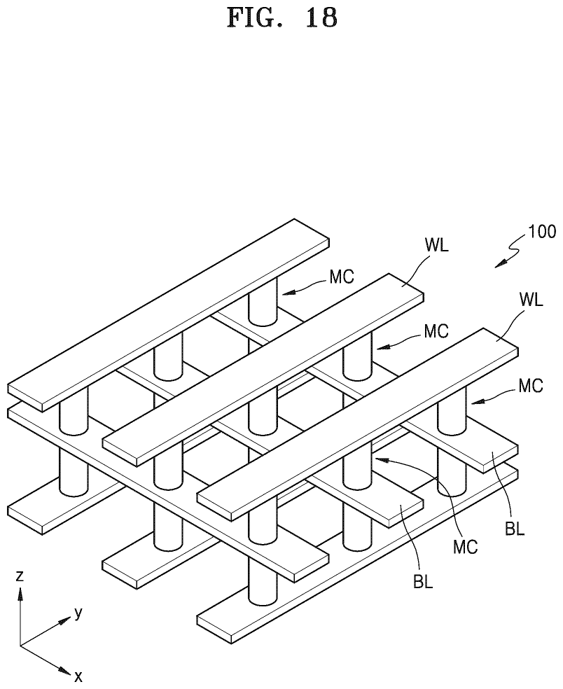

In this way, the memory device 10 according to various example embodiments may include any one or both of the first intermediate layer 15 and the second intermediate layer 17. For example, the memory device 10 according to various example embodiments may have a structure in which an intermediate layer including a crystalline chalcogenide-based material is inserted into an interface of the electrode. As a result, as will be described later with reference to FIGS. 16 and 17, it is possible to prevent or reduce the constituent element of the memory layer 13 from diffusing toward the first electrode 11 or the second electrode 12, and thus, an endurance of the memory device 10 may be improved.

FIG. 4 is a graph showing voltage-current characteristics of the memory layer 13 of the memory device 10 according to various example embodiments.

Referring to FIG. 4, the memory layer 13 may have one of a first state (LVS; low Vth state) in which a threshold voltage is relatively low and a second state (HVS; high Vth state) in which a threshold voltage is relatively high. For example, in the first state, the threshold voltage of the memory layer 13 is a first voltage V1, and in the second state, the threshold voltage of the memory layer 13 is a second voltage V2 higher than the first voltage V1.

When the memory layer 13 is in the first state, if a voltage lower than the first voltage V1 is applied to the memory layer 13, almost no current flows between both ends of the memory layer 13, and if a voltage higher than the first voltage V1 is applied to the memory layer 13, the memory layer 13 is turned on and a current flows through the memory layer 13. In addition, when the memory layer 13 is in the second state, if a voltage lower than the second voltage V2 is applied to the memory layer 13, almost no current flows between both ends of the memory layer 13, and if a voltage higher than the second voltage V2 is applied to the memory layer 13, the memory layer 13 is turned on and a current flows through the memory layer 13.

Therefore, a voltage between, e.g., half-way between, the first voltage V1 and the second voltage V2 may be selected as a read voltage VR, and in a read operation, a read voltage VR between the first voltage V1 and the second voltage V2 may be applied to the memory layer 13. When the memory layer 13 is in the first state, if the read voltage VR is applied to the memory layer 13, a current flows through the memory layer 13, and at this time, a data value stored in the memory layer 13 may be defined as a first binary value or a first logical value “1”. When the memory layer 13 is in the second state, if the read voltage VR is applied to the memory layer 13, almost no current flows through the memory layer 13, and at this time, data value stored in the memory layer 13 may be defined as a second binary value or a second logical value “0”. In other words, when a current flowing through the memory layer 13 is measured while applying the read voltage VR to the memory layer 13, the data value stored in the memory layer 13 may be read.

When the memory layer 13 is in the first state, if a negative bias voltage is applied to the memory layer 13 so that a current flows from the first electrode 11 to the second electrode 12, a threshold voltage of the memory layer 13 is increased and the memory layer 13 may be converted to the second state. For example, when a negative third voltage V3 is applied to the memory layer 13, the memory layer 13 may be converted to the second state. This operation may be referred to as a ‘RESET’ operation or an erase operation. In addition, when the memory layer 13 is in the second state, if a positive (+) bias voltage greater than the second voltage V2 is applied to the memory layer 13 so that a current flows from the second electrode 12 to the first electrode 11, the threshold voltage of the memory layer 13 may be lowered such that the memory layer 13 may be converted to the first state. This operation may be referred to as a ‘SET’ operation or program operation. A difference between the second voltage V2, which is the RESET threshold voltage, and the first voltage V1, which is the SET threshold voltage, may correspond to a memory window.

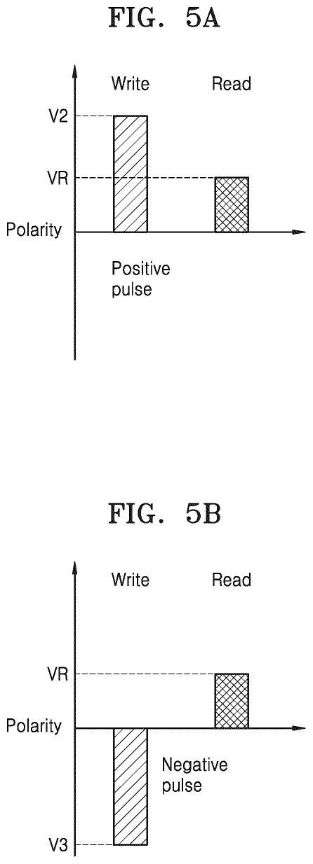

FIG. 5A is a graph illustrating bias voltages for a SET operation and a read operation in the memory device 10 according to various example embodiments.

Referring to FIG. 5A, in a SET operation, a positive bias voltage equal to or greater than the second voltage V2 may be applied to the memory layer 13. Then, a threshold voltage of the memory layer 13 may be shifted to the first voltage V1. Then, in a read operation, a positive read voltage VR between the first voltage V1 and the second voltage V2 may be applied to the memory layer 13. When the read voltage VR is applied, the memory layer 13 may be turned on.

FIG. 5B is a graph illustrating bias voltages for a RESET operation and a read operation in the memory device 10 according to various example embodiments.

Referring to FIG. 5B, a negative bias voltage, that is, a third voltage V3, may be applied to the memory layer 13 in a RESET operation. An absolute value of the third voltage V3 may be approximately equal to or slightly greater or less than the second voltage V2. Then, a threshold voltage of the memory layer 13 may be shifted to the second voltage V2, which is higher than the first voltage V1. Then, in a read operation, a positive (+) read voltage VR between the first voltage V1 and the second voltage V2 may be applied to the memory layer 13. When the read voltage VR is applied, the memory layer 13 may be turned off.

As described above, the memory layer 13 of the memory device 10 according to various example embodiments may include, for example, a GeAsSe or GeSbSe-based amorphous chalcogenide material layer, and may have memory characteristics in which the threshold voltage changes while having ovonic threshold switching characteristic. The threshold voltage of the memory layer 13 may be shifted according to the polarity of the bias voltage applied to the memory layer 13. In this regard, the memory device 10 according to various example embodiments may be a self-selecting memory device having a polarity-dependent threshold voltage shift characteristic.

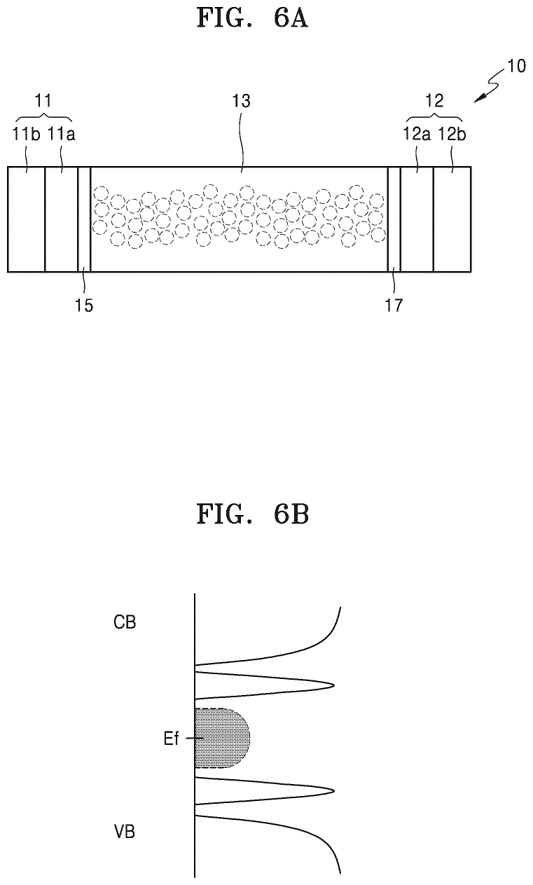

The polarity-dependent threshold voltage shift behavior may be explained through a change in a trap state inside the memory layer 13. FIGS. 6A to 8C are diagrams for conceptually explaining changes in a trap state within the memory layer 13.

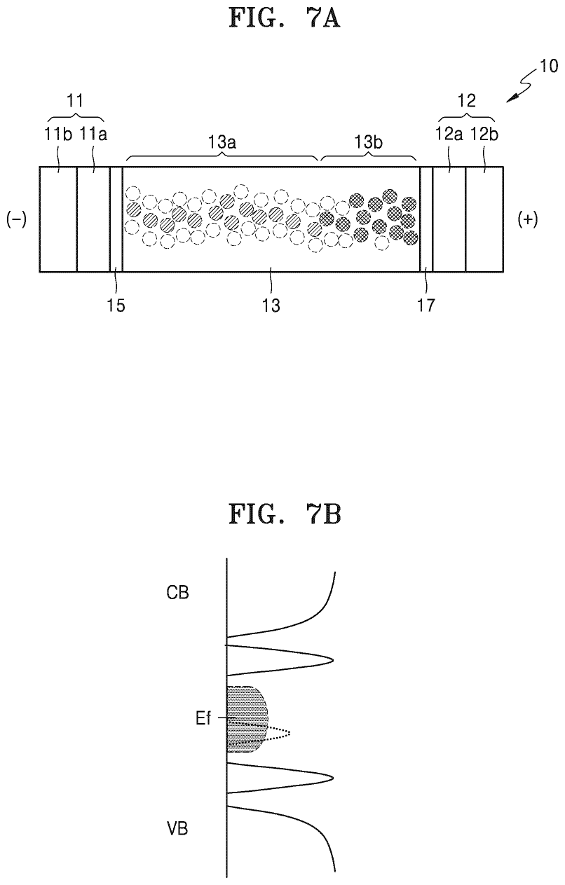

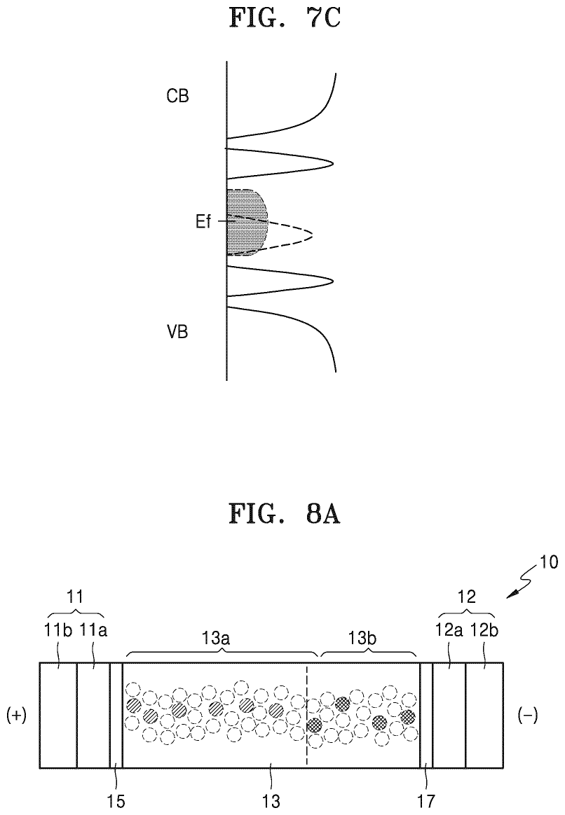

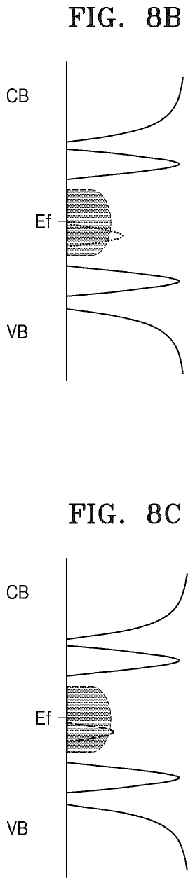

FIG. 6A is a conceptual diagram illustrating a trap state inside the memory layer 13 in a pristine (or virgin) state of the memory layer 13 of the memory device 10 according to various example embodiments, and FIG. 6B is a schematic energy band diagram for the memory layer 13 in the pristine (or virgin) state. FIG. 7A is a conceptual diagram illustrating a trap state inside the memory layer 13 after applying a positive bias voltage for first-firing to the memory layer 13 in the pristine state, FIG. 7B is a schematic energy band diagram for a region of the memory layer 13 near the first electrode 11 after the first-firing, and FIG. 7C is a schematic energy band diagram for a region of the memory layer 13 near the second electrode 12 after the first-firing. FIG. 8A is a conceptual diagram illustrating a trap state inside the memory layer 13 after applying a negative bias voltage to the first-fired memory layer 13, and FIG. 8B is a schematic energy band diagram for a region of the memory layer 13 near the first electrode 11 after applying the negative bias voltage, and FIG. 8C is a schematic energy band diagram for a region of the memory layer 13 near the second electrode 12 after applying the negative bias voltage.

Referring to FIG. 6A, de-activated traps mainly exist inside the memory layer 13 in the pristine state immediately after manufacturing. For convenience of explanation, de-activated traps are indicated by dotted circles in FIG. 6A. The de-activated traps may be mainly formed by covalent bonds between neighboring atoms within the memory layer 13. For example, when the memory layer 13 includes a GeAsSe and/or a GeSbSe-based amorphous chalcogenide material layer, the de-activated traps may be mainly formed by covalent bonds (Se—Se) between neighboring selenium (Se) atoms within the memory layer 13.

Also, in graph of FIG. 6B, ‘CB’ represents a conduction band, ‘VB’ represents a valence band, and the horizontal axis represents the density of states. Referring to FIG. 6B, an energy band formed by the de-activated traps is indicated by a thin dashed line. The energy band indicated by a solid line in FIG. 6B is formed by other materials in the memory layer 13. The energy band formed by the de-activated traps may be distributed around the Fermi level (Ef).

In order to first-fire the memory layer 13 that is in a pristine state, a positive bias voltage may be applied to the memory layer 13. For example, a bias voltage may be applied to the memory layer 13 so that a current flows from the second electrode 12 to the first electrode 11. Referring to FIG. 7A, some of the de-activated traps may be activated by first-firing, and thus, activated traps may be formed. The activated traps may be mainly formed by Se ions (Se²⁻) generated by breaking covalent bonds between Se atoms. A percolation path and/or conduction path may be formed within the memory layer 13 by the activated traps, and a threshold voltage of the memory layer 13 may be lowered by forming such a percolation path or conduction path.

In FIG. 7A, activated traps are indicated by circles in a hatched pattern and circles in a mesh pattern. As shown in FIG. 7A, the amount of activated traps within the memory layer 13 may increase from the first electrode 11 to the second electrode 12. In particular, a larger amount of activated traps may occur in a region of the memory layer 13 close to the second electrode 12. Accordingly, after first-firing, the memory layer 13 may include a first region 13a with a relatively low density of activated traps and a second region 13b with a relatively high density of activated traps. A thickness of the second region 13b may be less than the thickness of the first region 13a. For example, the total thickness of the memory layer 13 may be in a range from about 10 nm to about 30 nm, and the thickness of the second region 13b may be in a range from about 1 nm to about 4 nm. However, the thickness is not limited thereto.

The first region 13a is or corresponds to a region adjacent to the first electrode 11. The activated traps in the first region 13a are indicated by circles in a hatched pattern. The density of activated traps within the first region 13a may gradually increase as it approaches the boundary with the second region 13b, but the amount of increase may be relatively small. The second region 13b is or corresponds to a region adjacent to the second electrode 12. Additionally, the second region 13b directly contacts the first region 13a and may be located between the first region 13a and the second electrode 12. The activated traps in the second region 13b are indicated by circles in a mesh pattern. The density of activated traps within the second region 13b may increase relatively significantly as it approaches the boundary with the second electrode 12. Accordingly, the density of activated traps in the second region 13b may be higher than the density of activated traps in the first region 13a. In this case, the memory layer 13 is in a first state in which the threshold voltage is relatively low. For example, when the memory layer 13 is in the first state, the density of activated traps in the second region 13b may be higher than the density of activated traps in the first region 13a.

Referring to FIG. 7B, the energy band formed by the activated traps within the first region 13a is indicated by a dotted line. The energy band formed by the activated traps may be located at an energy level slightly lower than the Fermi level (Ef). Additionally, referring to FIG. 7C, the energy band formed by the activated traps within the second region 13b is indicated by a thick dashed line. When comparing FIGS. 7B and 7C, it may be seen that the energy band formed by the activated traps in the second region 13b has a slightly wider energy distribution than the energy band formed by the activated traps in the first region 13a. Also, it may be seen that a state density of activated traps in the second region 13b is greater than a state density of activated traps in the first region 13a. Accordingly, it may be seen that the amount of activated traps in the second region 13b is greater than the amount of activated traps in the first region 13a.

The high activated trap density near the second electrode 12 after first-firing may have a significant impact on the behavior of the threshold voltage shift of the memory layer 13. For example, the activated trap density in the second region 13b may be relatively easily changed depending on the polarity of a bias voltage, and accordingly, a threshold voltage of the memory layer 13 may be relatively easily shifted. Therefore, a relatively easy SET operation and/or a relatively easy RESET operation may be possible.

When a negative bias voltage is applied to the first-fired memory layer 13, in other words, when a bias voltage is applied to the memory layer 13 in a reverse direction so that a current flows from the first electrode 11 to the second electrode 12, some of the activated traps in the second region 13b close to the second electrode 12 are annihilated and changed into de-activated traps. This may be explained by, for example, neighboring Se ions (Se²⁻) being combined again to form a covalent bond (Se—Se). As a result, the density of activated traps within the memory layer 13 decreases.

Comparing FIGS. 7A and 8A, after applying a negative bias voltage to the memory layer 13, the density of activated traps may decrease in both the first region 13a and the second region 13b. The density of activated traps in the second region 13b may further be decreased. On the other hand, the density change amount of activated traps in the first region 13a may be less than the density change amount of activated traps in the second region 13b. Accordingly, after applying the negative bias voltage to the memory layer 13, the density of activated traps in the second region 13b may be less than the density of activated traps in the first region 13a. As a result, an interface tunneling barrier (ITB) or a space charge region may be formed near a boundary between the first region 13a and the second region 13b.

Also, comparing FIGS. 7B and 8B, after applying a negative bias voltage to the memory layer 13, the state density of activated traps in the first region 13a may slightly decrease. On the other hand, comparing FIGS. 7C and 8C, after applying a negative bias voltage to the memory layer 13, the state density of activated traps in the second region 13b may be relatively significantly decreased. In addition, comparing FIGS. 8B and 8C, after applying a negative bias voltage to the memory layer 13, it may be seen that the state density of activated traps in the second region 13b is less than the state density of activated traps in the first region 13a.

When the amount of activated traps in the memory layer 13, especially in the second region 13b close to the second electrode 12, is reduced, a larger bias voltage is required or expected to form an electrical conduction path, and thus, a threshold voltage of the memory layer 13 may increase. At this time, the memory layer 13 is in a second state in which a threshold voltage is relatively high. In other words, when the memory layer 13 is in the second state, the density of activated traps in the second region 13b may be lower than the density of activated traps in the first region 13a. In addition, when the memory layer 13 is in the second state, the activated trap density in the first region 13a and the activated trap density in the second region 13b may respectively be less than the activated trap density in the first region 13a and the activated trap density in the second region 13b when the memory layer 13 is in the first state.

Then, when a positive bias voltage higher than a threshold voltage is applied to the memory layer 13, the amount of activated traps increases in the memory layer 13, especially in the second region 13b, and thus, the threshold voltage of the memory layer 13 may be lowered again. Then, the memory layer 13 may be in the first state.

In this way, in the case of the memory device 10 according to various example embodiments, a threshold voltage shift behavior may be implemented through a change in the state of the activated traps within the memory layer 13, especially through a large change in the state of the activated traps in the second region 13b of the memory layer 13 close to the second electrode 12. Meanwhile, because the density of activated traps in the pristine state is lower than the density of activated traps when a negative bias voltage is applied after first-firing, a positive bias voltage required for first firing may be greater than a positive bias voltage for lowering a threshold voltage of the memory layer 13 again after the negative bias voltage.

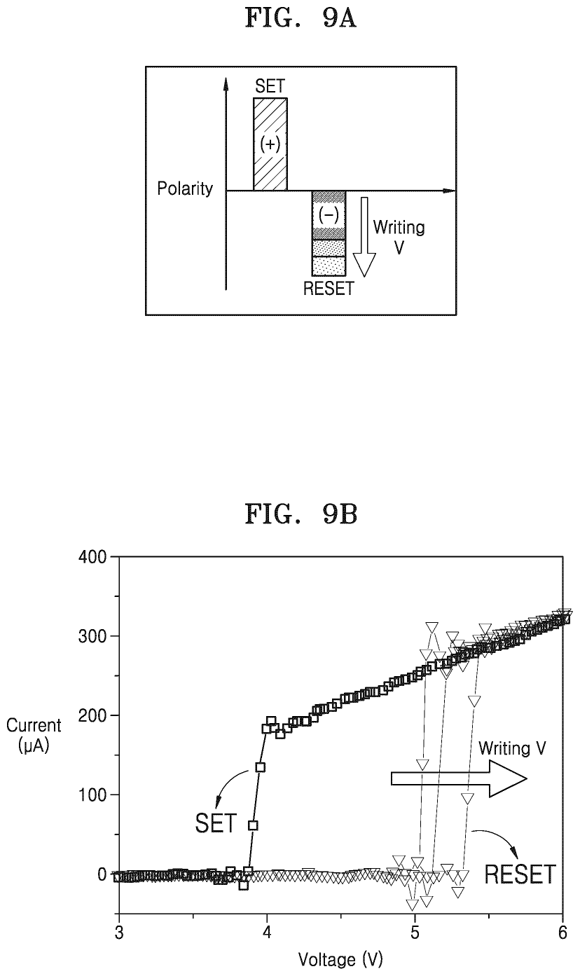

FIG. 9A is a graph illustrating bias voltages of a RESET operation and a SET operation for writing applied to the memory layer 13 of the memory device 10 according to various example embodiments. FIG. 9B is a graph illustrating voltage-current characteristics according to the magnitude (strength) of a write voltage applied to the memory layer 13 of the memory device 10 according to various example embodiments.

Referring to FIGS. 9A and 9B, when a write voltage applied to the memory layer 13 is a voltage of positive (+) polarity, a SET threshold voltage does not change even when the magnitude (strength) of the voltage increases. On the other hand, when the write voltage applied to the memory layer 13 is a voltage of negative (−) polarity, it may be seen that the RESET threshold voltage increases as the magnitude (strength) of the voltage V increases. Accordingly, a multi-level memory, e.g., a memory in which mor than one bit is stored in each memory cell, may be implemented in the memory layer 13 by changing the magnitude of a voltage of negative (−) polarity.

As described above, the memory layer 13 of the memory device 10 according to various example embodiments may have an ovonic threshold switching characteristic and at the same time have a memory characteristic in which the threshold voltage changes. In particular, a threshold voltage of the memory layer 13 may be shifted depending on the polarity of a bias voltage applied to the memory layer 13.

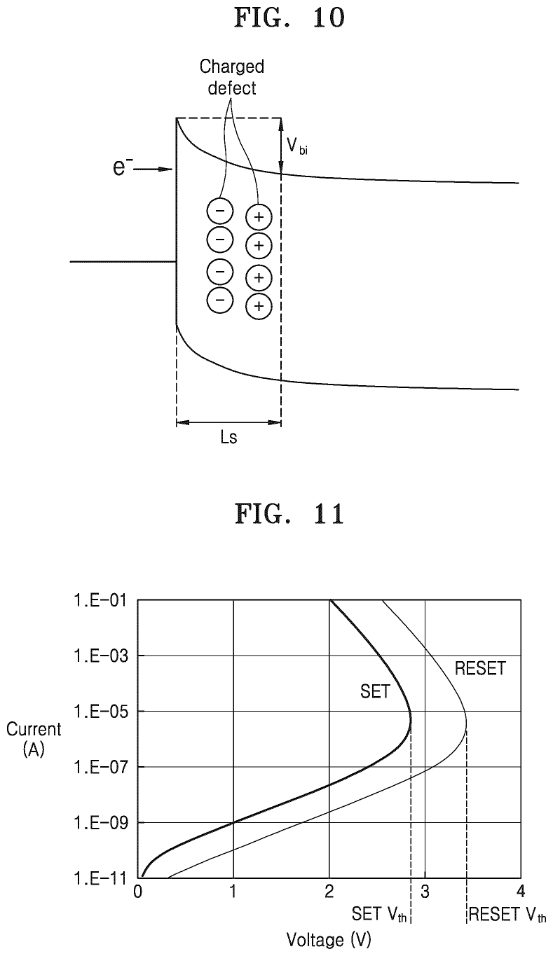

FIG. 10 shows a schematic band diagram of a space charge region formed by a RESET operation in the memory device 10 according to various example embodiments.

Referring to FIG. 10, during a RESET operation, charged defects with different polarities may be accumulated near an interface of the memory layer 13, and a space charge region may be formed due to band bending. This space charge region may perform as an electrical barrier that prevents or reduces electron injection during a read operation. In FIG. 10, “Ls” refers to a length of the space charge region, and “V_{bi}” refers to a built-in potential or potential barrier.

Ls may be calculated by the following equation.

$${L}_{S} = \sqrt{\frac{2 {ε}_{0} {ε}_{r}}{{qN}_{t}} ( {V}_{bi} - V )}$$

Here, ε₀ represents permittivity of vacuum, εᵣ represents dielectric permittivity, Nₜ represents trap density, V_{bi} represents built-in potential, q represents charge amount, and V represents an applied voltage. When a length Ls of the space charge region is, for example, 1 nm or more, the threshold voltage shift characteristic for a self-selecting memory device may be secured. However, the length Ls of the space charge region is not limited thereto.

FIG. 11 is a simulation result illustrating an I-V curve (current-voltage curve) showing the generation of a memory window in the memory device 10 according to various example embodiments by modeling the result shown in FIG. 10. Referring to FIG. 11, it may be seen that a memory window is created as the threshold voltage (RESET Vth) in the reset (RESET) operation increases than the threshold voltage (SET Vth) in the set (SET) operation.

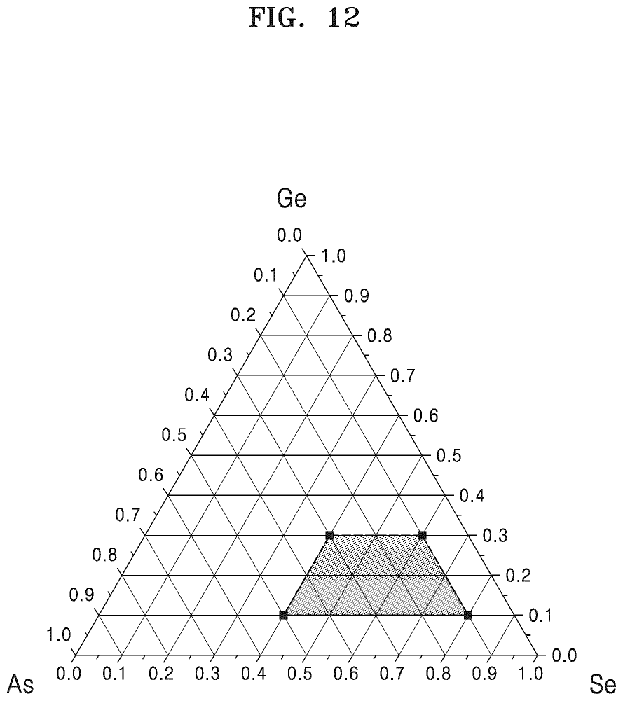

FIG. 12 is a graph illustrating an elemental composition ratio of materials of the memory layer 13 of the memory device 10 according to various example embodiments. For example, when GeAsSe is used as the material of the memory layer 13, the ratio of germanium (Ge) in the memory layer 13 may be in a range from about 10 at % to about 30 at %, the ratio of arsenic (As) may be in a range from about 10 at % to about 50 at %, and the ratio of selenium (Se) may be in a range from about 40 at % to about 80 at %. FIG. 12 illustrates the composition of GeAsSe used as the material of the memory layer 13, but when other materials are used, the composition is not limited thereto, and the composition may vary slightly. In various example embodiments, traps are mainly formed by Se, in the case when other materials are used, the ratio of Se in the material of the memory layer 13 may be about 40 at % or more.

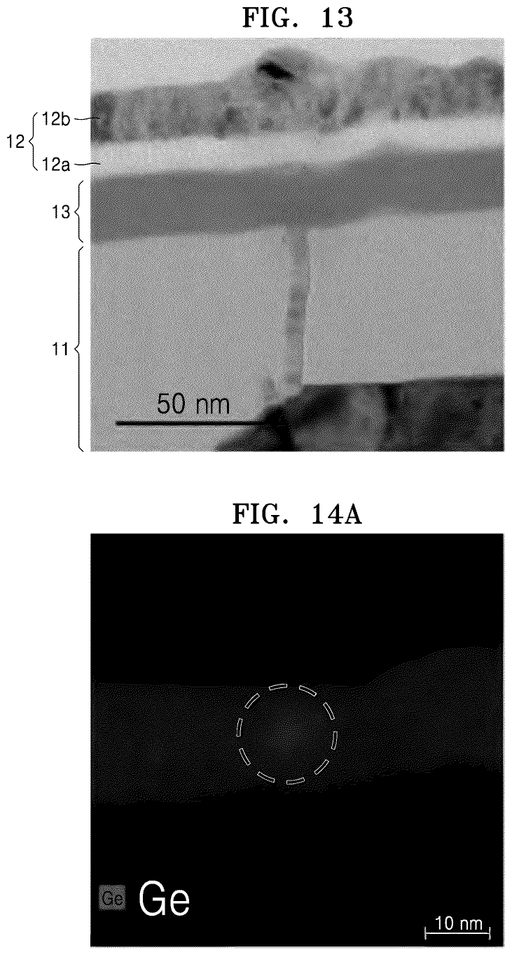

FIG. 13 illustrates a transmission electron microscope (TEM) photograph of a memory device sample of a comparative example that is actually manufactured. Referring to FIG. 13, in the actually manufactured memory device sample of a comparative example, the first electrode 11 includes only an electrode layer, and the second electrode 12 includes an electrode layer 12b and a barrier layer 12a.

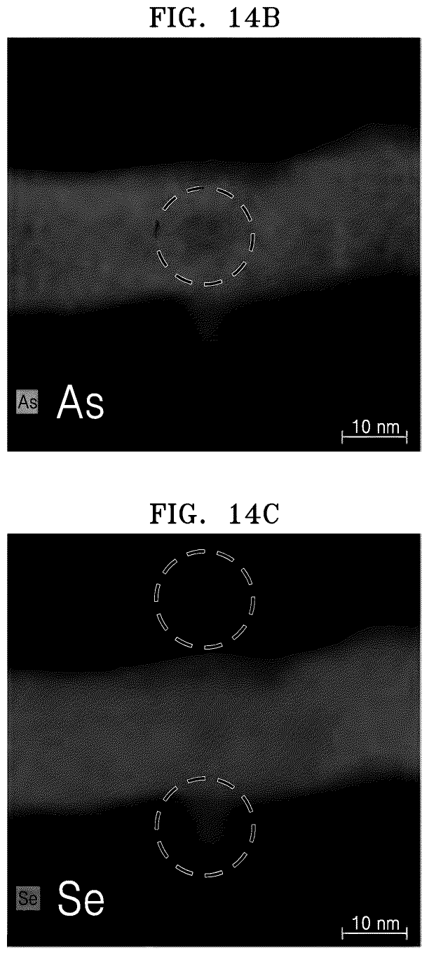

FIGS. 14A, 14B, and 14C illustrate results of element mapping for the GeAsSe-based memory layer 13 of the memory device sample of the comparative example shown in FIG. 13. In particular, FIGS. 14A, 14B, and 14C are photographs of a memory device sample of a comparative example in which an endurance failure of a GeAsSe-based self-selecting memory has occurred, analyzed by transmission electron microscopy (TEM) energy dispersive spectroscopy (EDS). The portions indicated by dotted circles illustrate portions where changes have occurred in the distribution of the Ge element, the distribution of the As element, and the distribution of the Se element.

Referring to FIGS. 14A, 14B, and 14C, when endurance failure occurs after several repeated operations of the comparative example memory device sample, the movement of Ge elements, As elements, and Se elements from the memory layer 13 is confirmed. In particular, it may be confirmed that the electrode is deteriorated as As and Se elements move or migrate toward the first electrode 11. In addition, the Se element moves not only in a direction of the first electrode 11 but also in a direction of the second electrode 12 including the electrode layer 12b and the barrier layer 12a, thereby confirming the phenomenon of electrode deterioration. From this result, it may be confirmed that even when the first electrode 11 or the second electrode 12 is provided with the barrier layer 11a or 12a, the constituent elements of the memory layer 13 may move, and thus, the electrode may be deteriorated.

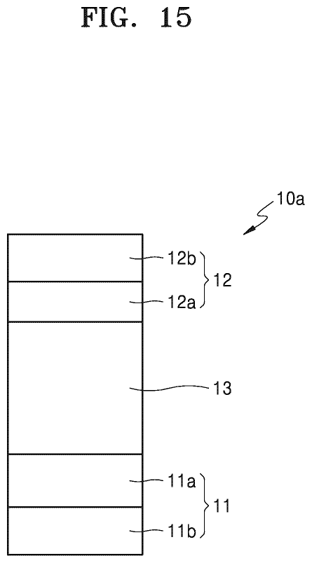

FIG. 15 is a schematic cross-sectional view showing a structure of a memory device 10a of a comparative example. Compared to the memory device 10 according to various example embodiments of FIGS. 1 to 3, the memory device 10a of the comparative example of FIG. 15 has a structure in which neither the first intermediate layer 15 nor the second intermediate layer 17 are included. That is, the memory device 10 according to various example embodiments described above with reference to FIGS. 1 to 3 includes an intermediate layer 15 and/or 17 including a crystalline chalcogenide-based material between the memory layer 13 and the electrodes 11 and/or 12. On the other hand, the memory device 10a of the comparative example shown in FIG. 15 corresponds to a structure without the intermediate layers 15 and 17.

FIGS. 16 and 17 show a comparison of the diffusion of constituent elements of the memory layer 13 in the memory device 10a of a comparative example and the memory device 10 of various example embodiments.

As shown in FIG. 16, in the memory device 10a of the comparative example, the constituent elements of the memory layer 13 may diffuse to the electrodes 11 or 12, and this diffusion may deteriorate the endurance of the memory device 10a.

On the other hand, as may be seen in FIG. 17, in the memory device 10 according to various example embodiments, the crystalline chalcogenide-based material of the intermediate layer 15 or 17 located between the memory layer 13 and the electrode 11 or 12 has high conductivity, and thus, acts like an electrode material and has a more stable bonding state. Thus, the constituent elements do not diffuse well into surrounding materials. Alternatively or additionally, electrode materials including other metals may deteriorate electrical characteristics by diffusing and penetrating into the memory layer 13, for example, a GeAsSe-based amorphous chalcogenide material as the self-selecting memory operation of the memory device 10 is repeated, but the crystalline chalcogenide-based material has the same or similar composition as, for example, the amorphous GeAsSe material, and thus, the change in the electrical characteristics of the self-selecting memory may not occur. Accordingly, the endurance of the memory device 10 according to various example embodiments may be improved due to the effect of the crystalline chalcogenide-based material.

As described above, the memory device 10 according to various example embodiments may perform both a memory function and a selector function using only a single material by utilizing the density change phenomenon of activated traps depending on the polarity and strength of a bias voltage. Therefore, a unit memory cell of a memory apparatus may be implemented with only one memory device 10 without a separate selector. In addition, because both the memory function and the selector function may be performed with one memory layer 13, a memory apparatus including the memory device 10 according to various example embodiments may reduce an aspect ratio of a unit memory cell, and thus, the memory apparatus may be manufactured by a relatively simple process and may have an improved memory capacity. Alternatively or additionally, by inserting a crystalline chalcogenide material-based intermediate layer into an electrode interface, for example, the diffusion of the constituent elements of the memory layer 13 by an electric field strongly applied to the memory layer 13 including, for example, a GeAsSe-based amorphous chalcogenide material may be prevented or reduced. In addition, electrode materials including other metals may deteriorate electrical characteristics by diffusing and penetrating into the memory layer 13, for example, a GeAsSe-based amorphous chalcogenide material as the self-selecting memory operation of the memory device 10 is repeated, but the crystalline chalcogenide-based material has the same or similar composition as, for example, the amorphous GeAsSe material, and thus, the change in the electrical characteristics of the self-selecting memory may not cause. Therefore, according to the memory device 10 according to various example embodiments, a memory device with enhanced endurance may be implemented by inserting a crystalline chalcogenide material-based intermediate layer into an electrode interface.

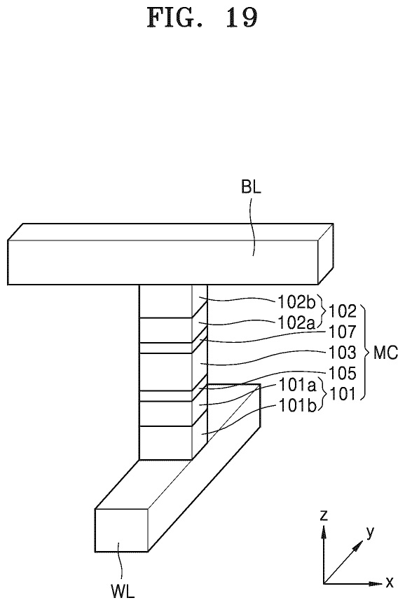

FIG. 18 is a schematic perspective view of a structure of the memory apparatus 100 according to various example embodiments. FIG. 19 is an enlarged view of one memory cell MC in the memory apparatus 100 shown in FIG. 18.

Referring to FIGS. 18 and 19, the memory apparatus 100 may have a three-dimensional cross point structure, such as two-square feature size (2F2) structure. For example, the memory apparatus 100 may include a plurality of bit lines BL extending in a first direction (i.e., x-axis direction), a plurality of word lines WL extending in a second direction (i.e., y-axis direction) crossing the first direction, and a plurality of memory cells MC provided at points where the plurality of bit lines BL and the plurality of word lines WL intersect.

Each of the plurality of memory cells MC may have a bar shape and/or a cylinder shape and may correspond to the memory device 10 according to various example embodiments described above with reference to FIGS. 1 to 3. For example, as illustrated in FIG. 19, each of the plurality of memory cells MC includes a lower electrode 101, an upper electrode 102 spaced apart from and facing the lower electrode 101, a memory layer 103 including an amorphous chalcogenide-based material disposed between the lower electrode 101 and the upper electrode 102, and an intermediate layer disposed between at least one of the lower electrode 101 and the upper electrode 102 and the memory layer 103. As illustrated in FIG. 19, each memory cell MC may include first intermediate layer 105 between the lower electrode 101 and the memory layer 103 and second intermediate layer 107 between the upper electrode 102 and the memory layer 103. Alternatively or additionally, each or at least some memory cells MC may have a structure including the second intermediate layer 107 without the first intermediate layer 105. Alternatively or additionally, each or at least some memory cells MC may have a structure including the first intermediate layer 105 without the second intermediate layer 107.

The lower electrode 101 and the upper electrode 102 may each correspond to the first electrode 11 and the second electrode 12 of the memory device 10 described above. For example, the lower electrode 101 may include an electrode layer 101b and may further include a barrier layer 101a. At this time, the barrier layer 101a and the electrode layer 101b may correspond to the barrier layer 11a and the electrode layer 11b of the first electrode 11 of the memory device 10 according to various example embodiments, respectively. Also, for example, the upper electrode 102 may include an electrode layer 102b and may further include a barrier layer 102a. At this time, the barrier layer 102a and the electrode layer 102b may correspond to the barrier layer 12a and the electrode layer 12b of the second electrode 12 of the memory device 10 according to various example embodiments, respectively. The first intermediate layer 105 and the second intermediate layer 107 may respectively correspond to the first intermediate layer 15 and the second intermediate layer 17 of the memory device 10 according to various example embodiments. Also, the memory layer 103 may correspond to the memory layer 13 of the memory device 10 according to various example embodiments. FIG. 19 illustrates an example in which the memory cell MC corresponds to the memory device 10 shown in FIG. 1 but is not limited thereto. For example, the memory cell MC may correspond to the memory device 10 of various embodiments described with reference to FIGS. 1 to 3 or a modified example thereof.

In this structure, the memory cells MC may be driven by a potential difference between the word line WL and the bit line BL connected to both ends of each memory cell MC. For example, when the memory layer 103 is in a first state having a relatively low first threshold voltage, if a potential difference between the word line WL and the bit line BL is, for example, about-4V or less, the memory layer 103 may be converted to a second state having a relatively high second threshold voltage. When the memory layer 103 is in the second state having a relatively high second threshold voltage, if a potential difference between the word line WL and the bit line BL is greater than or equal to the second threshold voltage, for example, about +4V or more, the memory layer 103 may be converted to a first state having a relatively low first threshold voltage. When reading data written in the memory layer 103, a potential difference between the word line WL and the bit line BL may be between the first threshold voltage and the second threshold voltage, for example, from about +3V to about +3.5V.

As such, according to the memory apparatus 100 in which the memory device 10 according to various example embodiments is applied to a plurality of memory cells MC, because each memory cell MC includes at least one of the first intermediate layer 105 and the second intermediate layer 107 between at least one of the lower electrode 101 and the upper electrode 102 and the memory layer 103, it may be possible to prevent or reduce the constituent elements of the memory layer 103 from diffusing toward the lower electrode 101 or the upper electrode 102. As a result, an endurance of each memory cell MC and corresponding memory apparatus 100 may be improved.

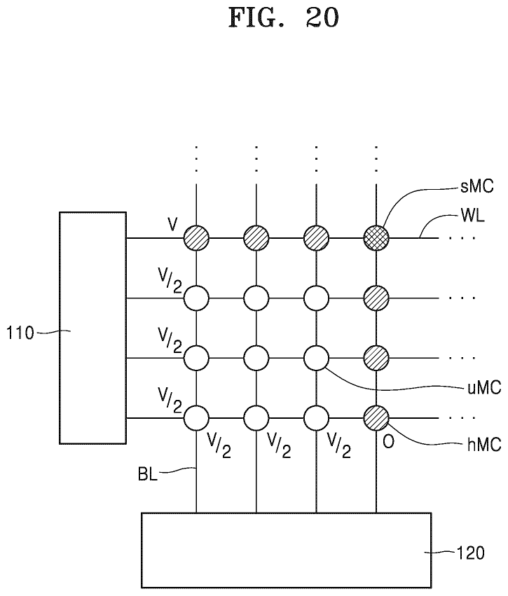

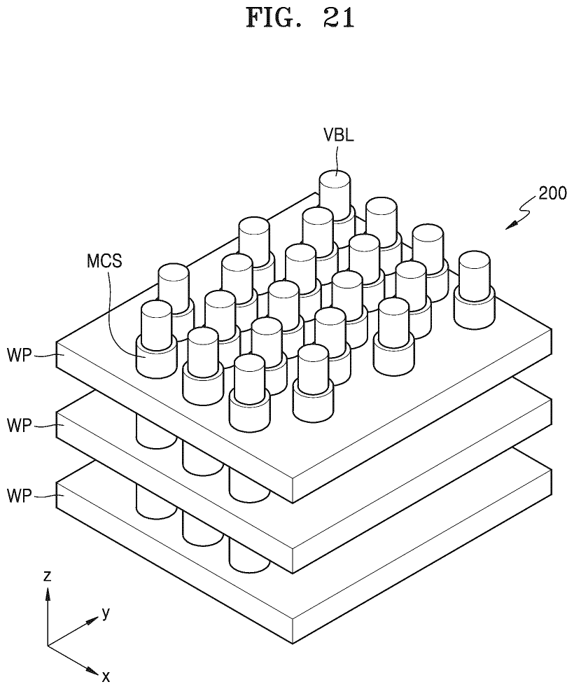

FIG. 20 is a plan view illustrating an operation of selecting a specific memory cell in the memory apparatus 100 shown in FIG. 18.

Referring to FIG. 20, the memory device 100 may further include a row decoder 110 that selectively supplies a voltage to at least one word line from among a plurality of word lines WL and a column decoder 120 that selectively supplies a voltage to at least one bit line from among a plurality of bit lines BL. In order to apply a voltage of V to one selected memory cell sMC among a plurality of memory cells MC, the row decoder 110 provides a voltage of V to the word line WL connected to the selected memory cell sMC and a voltage of, for example, V/2 may be provided to the remaining word lines WL. At this time, the column decoder 120 may provide a voltage of, for example, 0 V to the bit line BL connected to the selected memory cell sMC and a voltage of, for example, V/2 may be provided to the remaining bit lines BL.

Then, a potential difference between the word line WL and the bit line BL of the selected memory cell sMC becomes V. On the other hand, a potential difference between the word line WL provided with a voltage of V/2 and the bit line BL provided with a voltage of V/2 becomes 0 V. Accordingly, no voltage is applied to an unselected memory cell uMC disposed between the word line WL and the bit line BL that are not connected to the selected memory cell sMC. A voltage of V/2 may be applied to both ends of a quasi-selected memory cell hMC connected to the same word line WL as the selected memory cell sMC or connected to the same bit line BL as the selected memory cell sMC. The memory cell MC of the memory apparatus 100 according to various example embodiments is or includes a self-selecting memory device having a threshold voltage as described above, and in some cases does not include a separate access transistor. Accordingly, even when a voltage of V/2 is applied to the quasi-selected memory cell hMC adjacent to the selected memory cell sMC, the quasi-selected memory cell hMC is not turned on, and as a result, almost no sneak current is generated.

FIG. 21 is a schematic perspective view showing a structure of a memory apparatus 200 according to various example embodiments.

Referring to FIG. 21, the memory apparatus 200 may include a plurality of word planes WP extending along a plane including a first direction and a second direction and spaced apart in a third direction (e.g., z-axis direction) intersecting the first and second directions, a plurality of vertical bit lines VBL extending in the third direction and arranged two-dimensionally in the first and second directions, and a plurality of memory cell strings MCS extending in the third direction and surrounding surfaces of a plurality of vertical bit lines VBL. The plurality of memory cell strings MCS may be two-dimensionally arranged in the first and second directions similar to the plurality of vertical bit lines VBL. Each of the plurality of memory cell strings MCS and each of the plurality of vertical bit lines VBL may be arranged to pass through the plurality of word planes WP in the third direction. Because each of the plurality of memory cell strings MCS extends in the vertical direction, the memory apparatus 200 shown in FIG. 21 may be referred to as a vertical memory apparatus (e.g., vertical NAND or VNAND memory apparatus) and may have a further enhanced memory capacity. Each of the plurality of memory cell strings MCS may have components corresponding to the components of the memory device 10 according to various example embodiments described with reference to FIGS. 1 to 3, but the components may be formed in a shape surrounding the vertical bit line VBL.

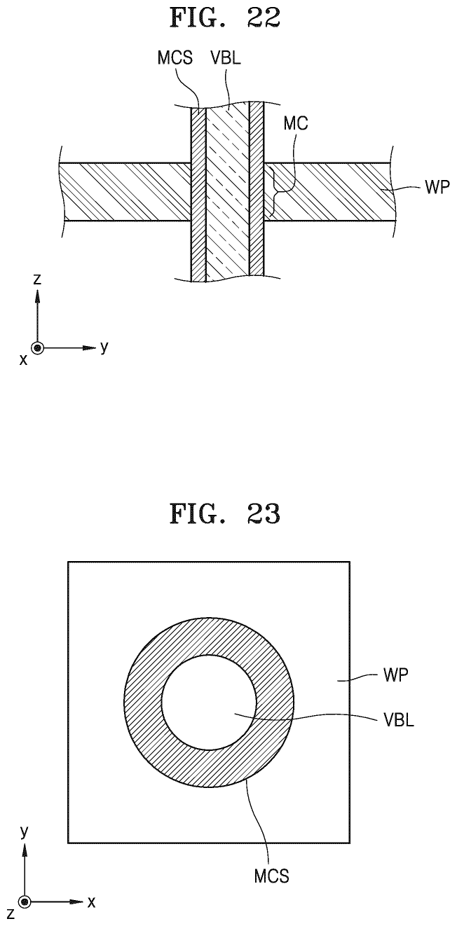

FIG. 22 is a schematic vertical cross-sectional view of a configuration of one memory cell in the memory apparatus 200 shown in FIG. 21. FIG. 23 is a schematic horizontal cross-sectional view of a structure of one memory cell in the memory apparatus 200 shown in FIG. 21.

Referring to FIGS. 22 and 23, a region surrounded by each word plane WP in the memory cell string MCS extending in the third direction may form one memory cell MC. Here, the memory cell MC may correspond to the memory device 10 according to various example embodiments described with reference to FIGS. 1 to 3.

For example, each memory cell string MCS may have a structure in which at least one intermediate layer and a memory layer corresponding to the at least one of the first intermediate layer 15 and the second intermediate layer 17 and the memory layer 13 of the memory device 10 surround a vertical bit line VBL and extend in the third direction. Alternatively or additionally, each memory cell string MCS may further include a barrier layer corresponding to the at least one of the barrier layer 11a of the first electrode 11 and the barrier layer 12a of the second electrode 12 of the memory element 10, and the barrier layer may surround the vertical bit line VBL and may extend in the third direction. Alternatively or additionally, each memory cell string MCS may include an electrode layer corresponding to the electrode layer 11b of the first electrode 11 and the electrode layer 12b of the second electrode 12, and the electrode layer may surround the vertical bit line VBL and may extend in the third direction. However, the word plane WP and the vertical bit line VBL may correspond to the electrode layers 11b and 12b of the first electrode 11 and the second electrode 12 of the memory device 10, respectively.

In this way, one memory cell string MCS may form a plurality of memory cells MC arranged to be spaced apart in the third direction. In addition, because the plurality of memory cell strings MCS are two-dimensionally arranged in the first and second directions, the plurality of memory cell strings MCS may form a plurality of memory cells MC arranged two-dimensionally in the first and second directions. At this time, the memory layer of each memory cell MC may correspond to the memory layer 13 of the memory device 10 described with reference to FIGS. 1 to 3 and may have the same characteristics as the memory layer 13. Also, each memory cell MC may include an intermediate layer including a crystalline chalcogenide-based material between the memory layer and at least one of electrodes on both sides of the memory layer or at least one of the word plane WP and the vertical bit line, and the intermediate layer may correspond to the first intermediate layer 15 and/or the second intermediate layer 17 of the memory device 10 described with reference to FIGS. 1 to 3. As a result, the diffusion of components of the memory layer of the memory cell string MCS into the electrodes on both sides of the memory layer or the word plane WP and the vertical bit line may be prevented or reduced, and thus, the endurance of each memory cell MC and the memory apparatus 200 including the memory cell may be improved.

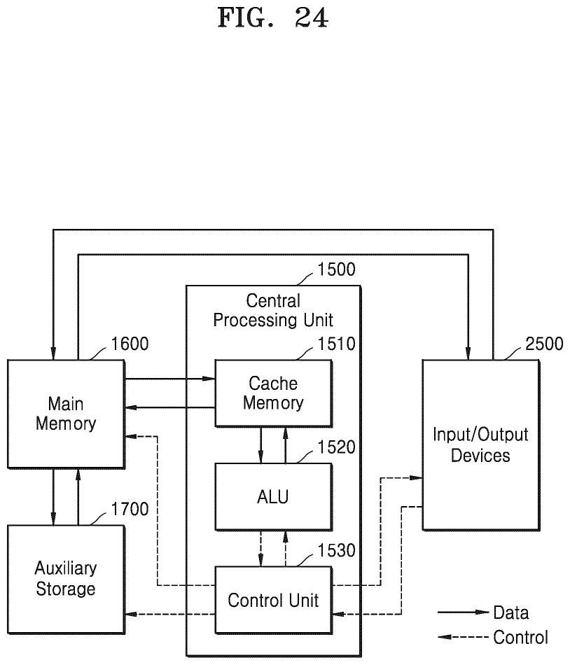

The memory apparatuses 100 and 200 according to various example embodiments described above may be used to store data in various electronic apparatuses. FIG. 24 is a schematic conceptual diagram of a device architecture that may be applied to electronic apparatuses according to embodiments.

Referring to FIG. 24, the electronic apparatus may include a main memory 1600, an auxiliary storage 1700, a central processing unit (CPU) 1500, and input/output devices 2500. The CPU 1500 may include a cache memory 1510, an arithmetic logic unit (ALU) 1520, and a control unit 1530. The cache memory 1510 may be configured of a static random access memory (SRAM). The main memory 1600 may include a DRAM device, and the auxiliary storage 1700 may include memory apparatus 100 and/or 200 according to various example embodiments. Alternatively or additionally, at least one of the cache memory 1510, the main memory 1600, and the auxiliary storage 1700 may include the memory apparatus 100 or 200 according to various example embodiments. In some cases, the device architecture of the electronic apparatus may be implemented in a form in which computing unit devices and memory unit devices are adjacent to each other on one chip, without distinction of sub-units.

The memory apparatus 100 or 200 according to various example embodiments described above may be implemented as a chip-shaped memory block and used as a neuromorphic computing platform or may be used to configure a neural network.

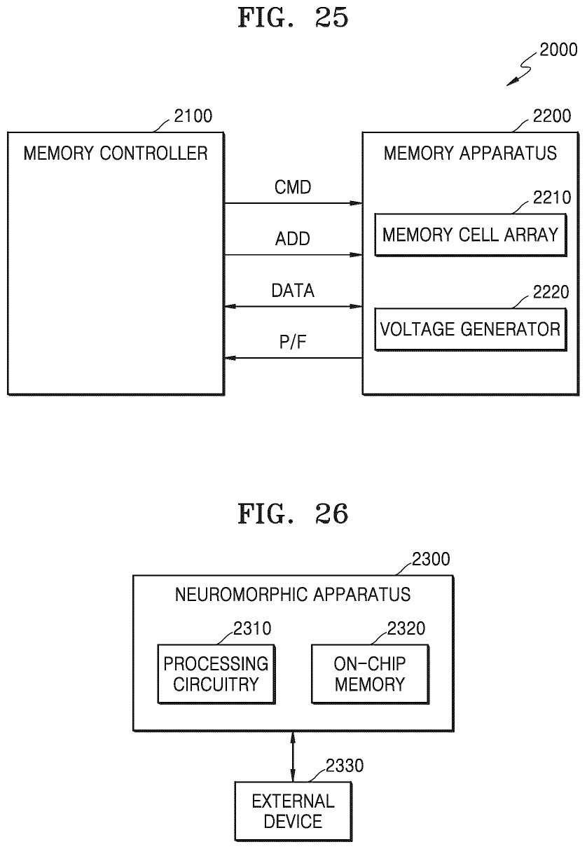

FIG. 25 is a block diagram of a memory system 2000 according to an exemplary embodiment.

Referring to FIG. 25, the memory system 2000 may include a memory controller 2100 and a memory apparatus 2200. The memory controller 2100 may perform a control operation on the memory apparatus 2200, and, for example, the memory controller 2100 may provide an address (ADD) to the memory apparatus 2200 and a command (CMD) to perform programming (or writing), read, and/or erase operations on the memory apparatus 2200. Additionally or alternatively, data for programming operations and read data may be transmitted between the memory controller 2100 and the memory apparatus 2200.

The memory apparatus 2200 may include a memory cell array 2210 and a voltage generator 2220. The memory cell array 2210 may include a plurality of memory cells and may include the memory apparatus 100 or 200 according to the exemplary embodiment described above.

The memory controller 2100 may include a processing circuit, such as hardware, including a logic circuit; a hardware/software combination, such as processor executing software; or any combination thereof. For example, the processing circuit may include, more specifically, one or more of a central processing unit (CPU), an arithmetic logic unit (ALU), a digital signal processor, a microcomputer, a field programmable gate array (FPGA), a system-on-chip (SoC), a programmable logic unit, a microprocessor, application-specific integrated circuit (ASIC), etc., but is not limited thereto. The memory controller 2100 may be configured to operate in response to a request from a host (not shown), access the memory apparatus 2200 and convert as a special purpose controller by controlling the control operations (e.g., write/read operations) described above. The memory controller 2100 may generate an address (ADD) and a command (CMD) to perform programming/read/erase operations on the memory cell array 2210. Also, in response to commands from the memory controller 2100, a voltage generator 2220 (e.g., a power circuit) may generate a voltage control signal for controlling a voltage level of a word line for data programming or data reading to the memory cell array 2210.

Alternatively or additionally, the memory controller 2100 may perform a decision operation on data read from the memory apparatus 2200. For example, the on-cell number and/or off-cell number may be determined from data read from a memory cell. The memory apparatus 2200 may provide a pass/fail signal (P/F) to the memory controller 2100 according to a read result of the read data. The memory controller 2100 may control write and read operations of the memory cell array 2210 by referring to the pass/fail (P/F) signals.

FIG. 26 is a block diagram showing a neuromorphic apparatus 2300 according to various example embodiments and an external device connected thereto.

Referring to FIG. 26, the neuromorphic apparatus 2300 may include a processing circuit 2310 and/or a memory 2320. The neuromorphic apparatus 2300 may include the memory apparatus 100 or 200 according to various example embodiments described above.

In some example embodiments, the processing circuit 2310 may be configured to control functions for driving neuromorphic apparatus 2300. For example, the processing circuit 2310 may be configured to control the neuromorphic apparatus 2300 by executing a program stored in the memory 2320. In some exemplary embodiments, the processing circuit 2310 may include hardware such as logic circuitry, a hardware/software combination such as a processor executing software, or any combination thereof. For example, the processor may include one or more of a CPU, a graphics processing unit (GPU), an application processor (AP) included in the neuromorphic apparatus 2300, an ALU, a digital signal processor, a microcomputer, a FPGA, an SoC, a programmable logic unit, a microprocessor, an ASIC, etc., but is not limited thereto. In some example embodiments, the processing circuit 2310 may be configured to read/write various data to external device 2330 and/or execute the neuromorphic apparatus 2300 using the read/written data. In some example embodiments, the external device 2330 may include an external memory and/or a sensor array having an image sensor (e.g., a CMOS image sensor circuit).

In some example embodiments, the neuromorphic apparatus 2300 of FIG. 26 may be applied to a machine learning system. The machine learning system may use various artificial neural network organizations and processing models, such as one or more of a convolutional neural network (CNN), a deconvolutional neural network, a recurrent neural network (RNN), optionally including a long short-term memory (LSTM) unit and/or a gated recurrent unit (GRU), a stacked neural network (SNN), a state-space dynamic neural network (SSDNN), a deep faith network (DBN), a generative adversarial network (GAN), and/or restricted Boltzmann machine (RBM).

Alternatively or additionally, the machine learning system may include other form of a machine learning model, for example, one or more of linear and/or logistic regression, statistical clustering, Bayesian classification, decision trees, dimensionality reduction such as principal component analysis, expert systems, and/or a combination thereof, including an ensemble such as random forests. The machine learning model may be used to provide a variety of services and/or applications, for example, one or more of an image classification service, a user authentication service based on biometric information or biometric data, an advanced driver assistance system (ADAS) service, a voice assistant service, an automatic voice recognition (ASR) service, etc. may be executed by an electronic apparatus.

Because the memory device according to various example embodiments has ovonic threshold switching characteristic and the threshold voltage thereof changes depending on a polarity and a strength of the applied voltage, both a memory function and a selector function may be performed. Therefore, a unit memory cell may be implemented with only one memory element without a separate selector. In the memory device according to various example embodiments, both the memory function and the selector function may be performed with one memory layer, so an aspect ratio of the memory device may be reduced, and the memory device may be manufactured through a relatively simple process. Alternatively or additionally, in the memory device according to various example embodiments, a crystalline chalcogenide-based intermediate layer is inserted into an interface of an electrode, and thus, the diffusion of constituent elements of the memory layer toward the electrode may be prevented or reduced. Accordingly, the endurance of the memory device may be enhanced.

A self-selecting memory device using the polarity-dependent threshold voltage shift method as described above, a memory apparatus including the same, and an apparatus including the memory apparatus have been described with reference to the embodiments shown in the drawings, but it will be understood by those of ordinary skill in the art that various changes in form and details may be made therein without departing from the spirit and scope of the disclosure. Therefore, various example embodiments should be considered in descriptive sense only and not for purposes of limitation. The scope of the disclosure is defined not by the detailed description of the disclosure but by the appended claims, and all differences within the scope will be construed as being included in the disclosure.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that various embodiments described herein should be considered in a descriptive sense only and not for purposes of limitation. Descriptions of features or aspects within each example embodiment should typically be considered as available for other similar features or aspects in other example embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a first electrode;
a second electrode spaced apart from the first electrode;
a memory layer between the first and second electrodes, having ovonic threshold switching characteristic, having a changeable threshold voltage that changes according to at least one of a polarity of and a strength of an applied voltage, and including an amorphous chalcogenide-based material; and
at least one of a first intermediate layer between the first electrode and the memory layer and including a crystalline chalcogenide-based material, or a second intermediate layer between the second electrode and the memory layer and including a crystalline chalcogenide-based material.

2. The memory device of claim 1, wherein
the memory device includes both the first intermediate layer and the second intermediate layer,
the first intermediate layer and the second intermediate layer have same or different thickness, and
the first intermediate layer and the second intermediate layer include a same crystalline chalcogenide-based material or include crystalline chalcogenide-based materials in which at least one element is different from each other.

3. The memory device of claim 1, wherein at least one of the first intermediate layer or the second intermediate layer has a thickness of 5 nm or less.

4. The memory device of claim 1, wherein at least one of the first intermediate layer or the second intermediate layer includes a crystalline chalcogenide-based material including at least one element selected from Se, Te, and S, and at least one element selected from Ge, As, and Sb.

5. The memory device of claim 1, wherein the memory layer includes an amorphous chalcogenide-based material including at least one element selected from Se, Te, and S, and at least one element selected from Ge, As, and Sb.

6. The memory device of claim 1, wherein the memory layer has one of a first state having a first threshold voltage and a second state having a second threshold voltage greater than the first threshold voltage.

7. The memory device of claim 6, wherein, in response to the memory layer being in the first state, the memory layer is converted into the second state by application of a negative bias voltage to the memory layer, and a current flows from the first electrode to the second electrode, and
in response to the memory layer being in the second state, the memory layer is converted into the first state by application of a positive bias voltage greater than the second threshold voltage to the memory layer, and a current flows from the second electrode to the first electrode.

8. The memory device of claim 6, configured to operate in a read operation such that a read voltage between the first and second threshold voltages is applied to the memory layer.

9. A memory apparatus comprising a plurality of memory cells,
wherein each of the plurality of memory cells includes:
a first electrode;
a second electrode spaced apart from the first electrode;
a memory layer between the first and second electrodes, having ovonic threshold switching characteristic, having a changeable threshold voltage that changes according to at least one of a polarity of and a strength of an applied voltage, and including an amorphous chalcogenide-based material; and
at least one of a first intermediate layer disposed between the first electrode and the memory layer and including a crystalline chalcogenide-based material, or a second intermediate layer disposed between the second electrode and the memory layer and including a crystalline chalcogenide-based material.

10. The memory apparatus of claim 9, wherein
each of the plurality of memory cells includes both the first intermediate layer and the second intermediate layer,
the first intermediate layer and the second intermediate layer have same or different thickness, and
the first intermediate layer and the second intermediate layer include the same crystalline chalcogenide-based material or include crystalline chalcogenide-based materials in which at least one element is different from each other.

11. The memory apparatus of claim 9, wherein at least one of the first intermediate layer or the second intermediate layer have a thickness of about 5 nm or less.

12. The memory apparatus of claim 9, wherein at least one of the first intermediate layer or the second intermediate layer includes a crystalline chalcogenide-based material including at least one element selected from Se, Te, and S, and at least one element selected from Ge, As, and Sb.

13. The memory apparatus of claim 9, wherein the memory layer includes an amorphous chalcogenide-based material including at least one element selected from Se, Te, and S, and at least one element selected from Ge, As, and Sb.

14. The memory apparatus of claim 9, wherein the memory layer has one of a first state having a first threshold voltage and a second state having a second threshold voltage greater than the first threshold voltage.

15. The memory apparatus of claim 14, wherein,
in response to the memory layer being in the first state, the memory layer is converted into the second state by application of a negative bias voltage to the memory layer and a current flows from the first electrode to the second electrode, and
in response to the memory layer being in the second state, the memory layer is converted into the first state by application of a positive bias voltage greater than the second threshold voltage to the memory layer and a current flows from the second electrode to the first electrode.

16. The memory apparatus of claim 14, configured to operate in a read operation such that a read voltage between the first and second threshold voltages is applied to the memory layer.

17. The memory apparatus of claim 9, further comprising:
a plurality of bit lines extending in a first direction; and
a plurality of word lines extending in a second direction intersecting the first direction,
wherein the plurality of memory cells have a three-dimensional cross point structure sat points where the plurality of bit lines and the plurality of word lines intersect.

18. The memory apparatus of claim 9, wherein the plurality of memory cells have a vertical NAND (VNAND) structure by being arranged in a third direction perpendicular to a plane including the first and second directions.

19. The memory apparatus of claim 18, further comprising:
a plurality of word planes extending along a plane including the first and second directions and spaced apart from each other in the third direction;
one or more vertical bit line passing through the plurality of word planes and extending in the third direction; and
one or more memory cell string surrounding the vertical bit line and extending in the third direction,
wherein the memory cell string has a portion surrounded by each word plane, the portion corresponding to the memory cell.

20. An electronic apparatus including the memory apparatus of claim 9.
